(19) United States
(12) Patent Application Publication
(10) Pub. No.: US 2005/0237726 A1
(43) Pub. Date: Oct. 27, 2005

(54) Semiconductor device and its manufacturing process, electro-optical equipment, and electronic equipment

(76) Inventor: Toshiaki Kori, Suwa (JP)

Correspondence Address: HARNESS, DICKEY & PIERCE, P.L.C., P.O. BOX 828, BLOOMFIELD HILLS, MI, 48303, US

(21) Appl. No.: 11/103,386

(22) Filed: Apr. 11, 2005

(30) Foreign Application Priority Data
Apr. 22, 2004 (JP) 2004-126936

(51) Int. Cl. H05K 7/02; H05K 7/06

(52) U.S. Cl. 361/760

(57) ABSTRACT

A semiconductor device includes a wiring substrate on which a semiconductor chip is mounted. A resin based insulating member is formed alongside of the semiconductor chip. A terminal of the semiconductor chip and a terminal of the wiring substrate are electrically connected through a wiring formed on the insulating member.

### RELATED APPLICATIONS

This application claims priority to Japanese Patent Application No. 2004-126936 filed Apr. 22, 2004 which is hereby expressly incorporated by reference herein in its entirety.

### BACKGROUND

1. Technical Field

The present invention relates to a semiconductor device and its manufacturing process, electro-optical equipment, and electronic equipment, and more particularly to techniques of mounting a semiconductor chip on a wiring substrate.

2. Related Art

In COB (Chip On Board) techniques of mounting a semiconductor chip on a wiring substrate, a conventional technique called “wire bonding” is typically used to electrically connect the semiconductor chip and the wiring substrate through wiring. In addition, there is a method of connecting one terminal to another with an alloy layer or an electrical contact. (for example, refer to Japanese Unexamined Patent Publication No. 2000-216330).

In a technique of using wire bonding, making a wiring pitch superfine (for example, under 100 μm) is difficult. Further, in a technique of connecting one terminal to another with an alloy layer or an electrical contact, its connection processing step tends to be complicated. Also, an improvement of the reliability of electric connections is desired.

The present invention has been made in view of the above-mentioned circumstances. It is an object thereof to provide a semiconductor device and its manufacturing process which can simplify processing when electrically connecting a semiconductor chip and a wiring substrate, making a wiring pitch superfine, and improving the reliability of electrical connections.

It is also another object thereof to provide electro-optical equipment and electronic equipment which accomplish cost reduction and quality improvement.

### SUMMARY

To achieve the above-mentioned objects, a semiconductor device according to the present invention is provided with a wiring substrate on which a semiconductor chip is mounted, the semiconductor chip having a side on which an insulating part (member) constituted by a resin is provided. A terminal of the semiconductor chip and a terminal of the insulating part are electrically connected through a wiring formed on the insulating part.

Inasmuch as a terminal of the semiconductor chip and a terminal of the wiring substrate are electrically connected through wiring formed on the insulating part provided on the side of the semiconductor chip, the process of forming the wiring is simplified, the wiring pitch is made superfine, and the reliability of the electrical connections is improved.

The semiconductor chip may have a first surface facing the wiring substrate and a second surface opposite to the first surface, with the terminal of the semiconductor chip on the second surface.

The terminal of the semiconductor chip and the terminal of the wiring substrate may be formed at different heights relative to a surface of the wiring substrate.

In this case, it is preferable for the insulation part to have a slanted surface corresponding to the different heights. The slated surface of the insulating part facilitates the formation of the wiring.

In the semiconductor device, it is acceptable for the wiring to include a plated film formed according to a plating process.

By using the plating process, the making of a superfine pitch of the wiring and the processing to form the wiring can be easily simplified, and also secure electrical connections can be attained.

In this case, it is acceptable for the wiring to include an undercoat film which will become an undercoating of the plated film.

The undercoat film improves a junction strength of the plated film.

Electro-optical equipment of the present invention comprises the above-mentioned semiconductor device. Further, electronic equipment of the present invention comprises the above-mentioned semiconductor device. Low cost and quality improvement may be accomplished with the electro-optical equipment and the electronic equipment.

A manufacturing process of the present invention is a process of manufacturing a semiconductor device provided with a wiring substrate on which a semiconductor chip is mounted, comprising the steps of mounting an insulating part constituted by a resin on a side of the semiconductor chip; and forming wiring on the insulating part electrically connecting a terminal of the semiconductor chip and a terminal of the wiring substrate.

According to the manufacturing process of the semiconductor device, by forming the wiring, which electrically connects the terminal of the semiconductor chip and the terminal of the wiring substrate, on the insulating part provided at the side of the semiconductor chip, the process of forming the wiring is simplified, the wiring pitch is made superfine, and the reliability of electrical connections is improved.

In this case, it is preferable for the insulating part to have a slanted surface corresponding to the difference in a height between the terminal of the semiconductor chip and the terminal of the wiring substrate relative to a surface of the wiring substrate.

The slanted surface of the insulating part facilitates forming the above-mentioned wiring.

Further, by forming the above-mentioned wiring through the use of a plating process, making the wiring pitch superfine and simplifying the process of forming the wiring can be easily achieved, and secure electrical connections can be made.

### BRIEF DESCRIPTION OF THE DRAWINGS

FIG. 1 is a sectional view along line I-I of FIG. 2;

FIG. 2 is a plan view to explain a semiconductor device according to an embodiment of the present invention;

FIGS. 3A-FIG. 3C are diagrams to explain a manufacturing process of a semiconductor device according to an embodiment of the present invention;

FIG. 4 is a diagram to explain electro-optical equipment (organic EL equipment) according to an embodiment of the present invention; and

FIG. 5 is a perspective view of an embodiment of electronic equipment of the present invention.

### DETAILED DESCRIPTION

Preferred embodiments of the present invention will be described below with reference to the drawings

FIG. 1 is a diagram explaining a semiconductor device according to an embodiment of the present invention, and is a sectional view along line I-I.

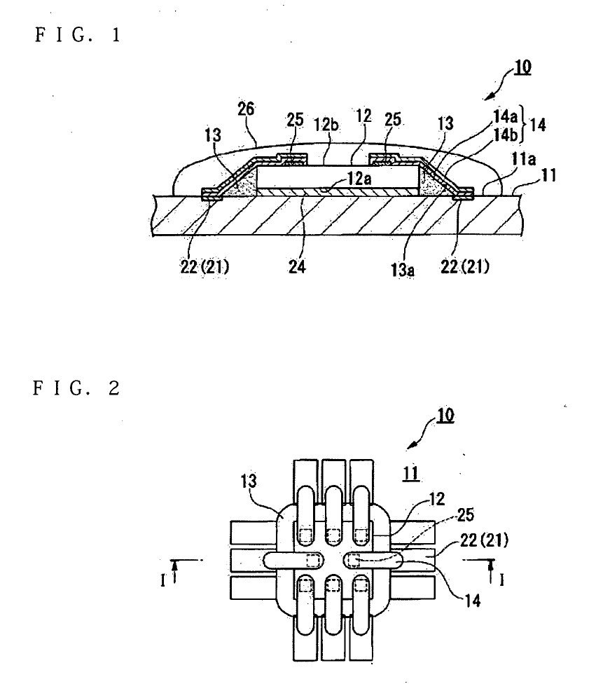

FIG. 2 is a plan view explaining a semiconductor device according to an embodiment of the present invention.

A semiconductor device 10 is configured by including a wiring substrate 11, a semiconductor chip (IC chip) 12 to be mounted on the wiring substrate 11, an insulating part (member) 13 formed at a side of the wiring substrate, wiring 14 electrically connecting the wiring substrate 11 and the semiconductor chip 12, and the like.

The wiring substrate 11 is formed of an insulating material such as a resin and ceramic. A wiring pattern 21 is formed on the wiring substrate 11. The wiring pattern 21 includes a terminal (terminal on a substrate side) 22 as an exposed portion formed on a mounting surface 11a of the semiconductor chip 12. The wiring pattern 21 may have an un-illustrated land (a portion wider than a line). Further, the wiring substrate 11 may be a multi-layer substrate (including a double-sided substrate). In this case, the multi-layer substrate includes a multi-layer (more than two layers) conductor pattern. Also, the wiring pattern 21 may include a conductor pattern built in the wiring substrate 11 (substrate). Further, the wiring substrate 11 may be a components mounted type wiring substrate built in a part. To be specific, inside the wiring substrate 11, passive parts such as a resistor, a capacitor, and an inductor or active parts such as an integrated circuit part may be connected electrically to the conductor pattern. Or a resistor may be formed by forming part of the conductor pattern with a material of a high resistance value. The wiring substrate 11 may be another chip larger than the semiconductor chip 12.

For example, an integrated circuit is formed on the semiconductor chip 12. The semiconductor chip 12 has a first surface 12a facing the wiring substrate 11 and a second surface 12b (active surface) opposite the first surface 12a.

The first surface 12a of the semiconductor chip 12 may be electrically connected or may not be connected to an un-illustrated integrated circuit. A passivation film (electrically insulation film) may be formed or may not be formed on the first surface 12a. The first surface 12a may be formed of a semiconductor (or a conductor).

Further, an adhesive layer 24 lies between the first surface 12a of the semiconductor chip 12a and the wiring substrate 11. The adhesive layer 24 is constituted by, for example, an adhesive agent. If the adhesive agent 24 has a conductive property, it is possible to connect electrically the terminal 22 of the wiring substrate 11 and the first surface 12a of the semiconductor chip 12. Further, if the adhesive layer 24 has an electrical insulation property, it is possible to insulate electrically the terminal 22 of the wiring substrate 11 and the first surface 12a of the semiconductor ship 12.

On the other hand, a plurality of terminals 25 are formed on the second surface 12b of the semiconductor chip 12. The first surface 12a and the second surface 12b are formed, for example, in a quadrilateral (for example, a rectangle). A plurality of terminals 25 may be formed in a periphery (edge part) of the second surface 12b. For example, the plurality of terminals 25 may be arrayed along four sides of the second surface 12b or may be arrayed along two sides.

It should be noted that there may be formed on the second surface 12b at least a layer of a passivation film which is an un-illustrated electrical insulation film.

The passivation film may be formed of only a non-resin material (for example, SiO₂ or SiN), and on top of that there may further be included a film consisting of a resin (for example, a polyamide resin). In this case, it is preferable that an opening be formed so as to expose at least part (for example, a central portion) of the plurality of terminals 25.

An insulating part 13 is formed of a material (for example, a resin) having an electrical insulation property. The insulating part 13 may be formed of a material different from the adhesive layer 24. The insulating part 13 is provided on the side of (along side of) the semiconductor chip 12. The insulating part may surround the semiconductor chip 12, or may only be adjacent to the terminal 25 of the semiconductor chip. The insulating part 13 may be in contact with the side of the semiconductor chip 12. Namely, it may be such that no gap is formed between the insulating part 13 and the semiconductor chip 12. In the example shown in FIG. 1, the insulating part 13 is formed such that its height is about equal to or not exceeding the height (for example, about 20 μm) of the semiconductor chip 12. When the heights of the semiconductor chip 12 and the insulating part 13 are about the same, there is hardly any difference in a level between the insulating part 13 and the semiconductor chip 12. It is acceptable for the insulating part 13 to cover only a portion made up of the semiconductor or the conductor out of the sides of the semiconductor chip 12.

Further, the insulating part 13 has a slanted surface 13a declining from the semiconductor chip 12 in an outward direction corresponding to the difference in a level between the terminal 25 of the semiconductor chip 12 and the terminal 22 of the wiring substrate 11. The thickest portion of the insulating part 13 is closest to the semiconductor chip 12, while the thinnest portion is farthest from the semiconductor chip 12. The insulating part 13 may be formed above part of a wiring pattern 21 (to be specific, to its terminal 22).

A wiring 14 is formed on the insulating part 13. The wiring 14 runs over the insulating part 13, part thereof is distributed on the terminal 25 of the semiconductor chip 12, and another part thereof is distributed on the terminal 22 of the wiring substrate 11. Namely, the wiring 14 electrically connects the terminal 25 of the semiconductor chip 12 and the terminal 22 (wiring pattern 21) of the wiring substrate 11. The pattern of the wiring 14 includes, for example, a pattern of a line width of about 20 μm and a pitch of 50-100 μm.

Further, the wiring 14 includes an undercoat film 14a formed on the insulating part 13 and a plated film 14b formed on the undercoat 14a. The undercoat film 14a is constituted by a barrier layer (barrier metal) formed on a surface of the insulating part 13 and a seed layer (a seed electrode). The barrier layer prevents components of the plated film 14b from dissipating and is formed of TiW (titanium tungsten), TiN (titanium nitride), TaN (tantalum nitride), and the like. On the other hand, the seed layer serves as an electrode when the plated film 14b is formed by the plating process to be mentioned later and is formed of Cu, Au, Ag, and the like. The plated film 14b is composed of conductive materials of low electric resistance such as Cu and W. It should be noted that if the plated film 14b is formed of a conductive material which is poly-S (polysilicon) that is doped with impurities such as B and P, it is possible to dispense with the above-mentioned barrier layer.

It should be noted that in the semiconductor device 10, a sealant 26 sealing at least part of the semiconductor chip 12 is placed as appropriate. In this case, the sealant 26 at least seals, for example, an electrical connection between the wiring 14 and the terminal 25 of the semiconductor chip 12 and an electrical connection between the wiring 14 and the terminal 22 (wiring pattern 21) of the wiring substrate 11.

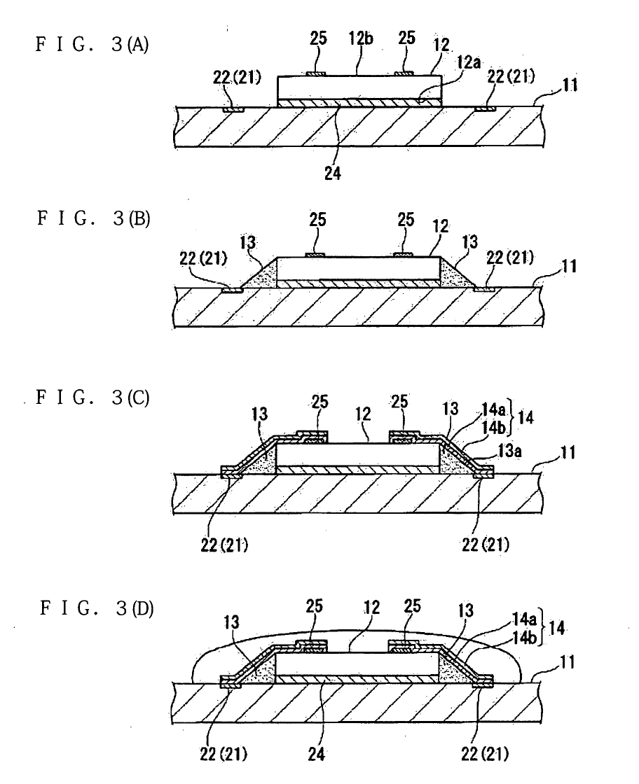

FIGS. 3A-C are diagrams explaining a manufacturing process of a semiconductor device according to the present invention. As shown in FIG. 3A, the semiconductor chip 12 is mounted on the wiring substrate 11. To be specific, it is mounted such that the second surface 12b (active surface) does not face the wiring substrate 11 (face-up mounting) so as to position its first surface 12a opposite the wiring substrate 11. In the present example, an adhesive agent is placed between the wiring substrate 11 and the semiconductor chip 12 to form the adhesive layer 24.

As shown in FIG. 3B, the insulating part 13 is formed on the side of the semiconductor chip 12. The insulating part 13 is formed by setting up a material different from the adhesive agent forming the adhesive layer 24. As materials forming the insulating part 13, resins such as polyimide resin, silicon denatured polyimide resin, epoxy resin, silicon denatured epoxy resin, benzocyclobutene (BCB), and polybenzoxazole (PBO) can be used. The insulating part 13 is formed so that it may have a slanted surface 13a declining from the semiconductor chip 12 to the outward direction. The insulating part 13 may be formed in such a way as to contact the side of the semiconductor chip 12. The insulating part 13 may be formed through plotting of a liquid resin or may be formed by sticking a dry film. Or after a material of the insulating part 13 is placed over the entire surface of the wiring substrate 11, the insulating part 13 may be formed by patterning. Due to gravity and the like, the material is placed slantwise corresponding to a height of the side of the semiconductor chip 12, and as a result, there is formed the insulating part 13 having the slanted surface 13a.

As shown in FIG. 3C, the wiring 14 is formed. The wiring 14 is formed so as to run from the terminal 25 of the semiconductor chip 12 over the insulating part 13 to above the terminal 22 of the wiring pattern 21. In the present example, after forming the undercoat film 14a, the plated film 14b is formed by the plating process. The details are described as follows.

First, the undercoat film 14a is formed.

To be specific, a barrier layer is formed at the undercoat film 14a, and a seed layer is formed thereon. The barrier layer and the seed layer are formed by using, for example, PVD (Physical Vapor Deposition) such as vacuum evaporation, sputtering, and ion plating, CVD, IMP (Ion Metal Plasma), and electroless plating, and the like.

Next, the plated film 14b is formed.

To be specific, first a photoresist is coated over the entire surface on top of the wiring substrate 11. As the photoresist, a liquid photoresist for plating or a dry film may be employed. It should be noted that a photoresist used when etching an Al electrode typically set up in a semiconductor device or a resin photoresist having an insulation property may be used, provided that it is resistant to a plating solution or an etching solution to be used in a process mentioned later. A photoresist coating is carried out by means of spin coating, dipping, spray coating and the like. Pre-baking is performed after photoresist coating.

Next, the photoresist is subjected to burning according to a planar shape of the plated film 14b (wiring 14) to be formed. To be specific, the photoresist is subjected to patterning by performing exposure processing and development processing with a mask on which a specified pattern is formed. The pattern of the wiring 14 includes, for example, a line width of approx. 20 μm and a pitch of about 50-100 μm.

Thereafter, with this photoresist as the mask, a conductive material is filled in an opening provided on the photoresist, thus forming the plated film 14b. Filling of the conductive material is performed by the plating process. For the plating process, for example, electro-optical plating (ECP) is employed. It should be noted that as an electrode in the plating process, a seed layer formed of the undercoat film 14a is used. By this means, the conductive material is filled in the opening formed on the photoresist, thus forming the wiring 14. Then, a remover and the like are used to remove the photoresist. It should be noted that for the remover, aqueous ozone and the like may be used. Next, in an area where the plated film 14b is not formed, the undercoat film 14a in an exposed state is removed by dry etching and the like.

Now, in the foregoing example, the plated film 14b was formed by way of filling the opening of the photoresist film, but it is not limited to this example. For example, by means of patterning after the plated film 14b is formed on the entire surface of the wiring substrate 11, there may be formed the plated film 14b (wiring 14) of a desired pattern.

Next, as shown in FIG. 3D, a sealant 26 is placed as necessary. The sealant 26 may be formed by a transfer mold or plotting. The sealant 26 may be omitted.

Through a series of steps described above, the semiconductor chip 12 is mounted on the wiring substrate 11. At the same time, the terminal 25 of the semiconductor chip 12 and the terminal 22 of the wiring substrate 11 are electrically connected by the wiring 14.

According to the present embodiment, forming the wiring is simplified, the wiring pitch is made super-fine, and the reliability of electrical connections is improved.

Despite the difference in levels between the terminal 25 of the semiconductor chip 12 and the terminal 22 of the wiring substrate 11 (the height differences), the insulating part 13 is formed on the side of the semiconductor chip 12, and connects between both terminals 22 and 25 with the wiring 14 running over this insulating part 13, so that processing from one side of the wiring substrate 11 is sufficient when electrically connecting the semiconductor chip 12 and the wiring substrate 11, thereby making it possible to use simple processing such as the plating process.

Since the insulating part 13 has the slanted surface 13a corresponding to the difference in levels between both terminals 22 and 25 and the wiring 14 is formed on this slanted surface 13a, the formation of the wiring is made easy and secure by comparison to a case of forming wiring on a vertical surface.

At this point, it is possible for the plating process to form a plurality of wirings in a single batch. Additionally, in combination with photolithography, it is easier to make the wiring pitch superfine (for example, under 100 μm). Further, in the present embodiment, the wiring 14 is formed by arranging the wiring material directly on the terminals 22 and 25, it is possible to make electrical connections of high reliability as compared to a technique of connecting with electrical contacts and the like.

Now, in the foregoing example, the slanted surface 13a of the insulating part 13 is assumed to be relatively flat, but it is not limited to this. For example, a concavity or a convexity may exist on the slanted surface 13a.

FIG. 4 is a diagram explaining an electro-optical device according to an embodiment of the present invention.

The electro-optical equipment of FIG. 4 is organic EL equipment 111 which is equipped to match an organic electro-luminescence (hereinafter referred to as “organic EL”) element to a pixel.

The organic EL equipment 111 is constituted by joining the wiring substrate 120 and an organic EL substrate 130 (light-emitting element substrate) through the use of an imprint technique called SUFTLA (Surface Free Technology by Laser Ablation) (registered trademark). Now, as for the above imprint technique, it is described, for example, in Japanese Unexamined Patent Publication No. Hei 10-125929, Japanese Unexamined Patent Publication No. Hei 10-125930, Japanese Unexamined Patent Publication No. Hei 10-125931, and the like.

The wiring substrate 120 comprises a multi-layer substrate 121, a wiring pattern 122 of a specified pattern formed thereon, a semiconductor chip 123 as a circuit part connected to the wiring pattern 122, a TFT (switching element) 124 driving the organic EL element 131, a TFT connecting part 125 joining the TFT 124 and the wiring pattern 122, and an organic EL connecting part 126 joining the organic EL element 131 and the wiring pattern 122.

At this point, the TFT connecting part 125 is formed according to a terminal pattern of the TFT 124. It is constituted by, for example, a bump (conductive protrusion) 125a formed by non-electrolytic plating and the like and a junction material 125b to be placed on the bump 125a.

An organic EL substrate 130 is formed of a transparent substrate 132 through which a ray of emitted light passes, a first electrode (anode) 133 made up of a transparent metal such as ITO, an organic functional layer (hole injection/transport layer 134, a light-emitting layer 135), a second electrode (cathode) 136, and a cathode separator 137. The hole injection/transport layer may be formed between the light-emitting layer 135 and the second electrode 136.

Further, a sealing paste 138 is filled between the wiring substrate 120 and the organic EL substrate 130, while there is provided a conductive paste 139 which permits electrical continuity between the organic EL connecting part 126 and the anode 136.

In the present embodiment, there are used techniques described from FIG. 1 to FIG. 3 above in connecting the semiconductor chip 123 and the wiring substrate 120. Namely, there is provided an insulation part 140 having a slanted surface on the side of the semiconductor chip 123, and through wiring 141 formed on this insulating part 140, the semiconductor chip 123 and the wiring substrate 120 are electrically connected. Consequently, as a result of simplifying the process of forming the wiring, making the wiring pitch superfine, and improving the reliability of electrical connections, low cost and quality improvement have been achieved for this organic EL device 111. It should be noted that the techniques described from FIG. 1 to FIG. 3 above may be used to connect the TFT 124 and the wiring substrate 129.

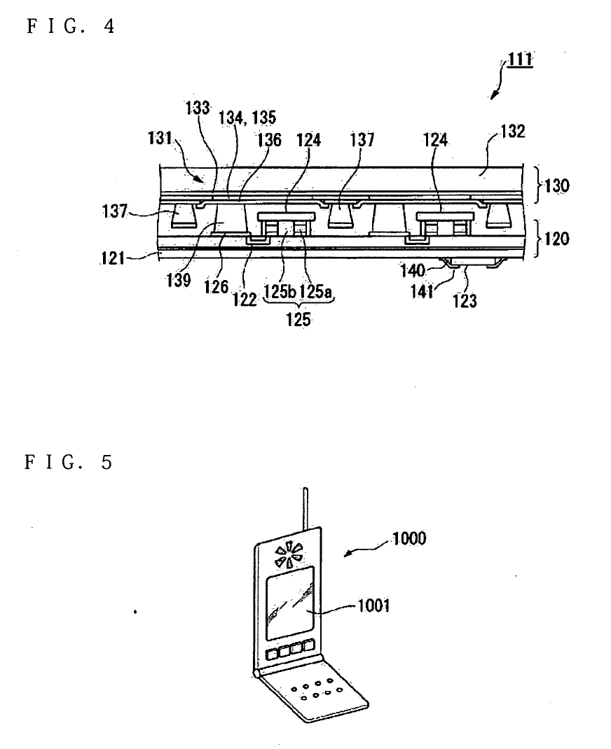

FIG. 5 shows an embodiment of electronic equipment of the present invention.

The electronic equipment of the present embodiment is mounted with the organic EL device 111 shown in FIG. 4 above as display means. FIG. 5 is a perspective view showing an example of a mobile phone, and a reference numeral 1000 indicates a mobile phone body, and a reference numeral 1001 indicates a display unit using the above-mentioned organic EL device 1. As a result of simplifying the process of forming the wiring, making the wiring pitch superfine, and improving the reliability of electrical connections, low cost and quality improvement have been achieved for this electronic equipment

While there has been described preferred embodiments according to the present invention with reference to the attached drawings, it is needless to say that the present invention is not restricted to such examples. Those skilled in the art will recognize that many variations and modifications are possible within the technical spirit and scope of the appended claims, and it is understood that all such variations and modifications fall within the scope of the present invention.

1. A semiconductor device comprising:
a wiring substrate;
a semiconductor chip mounted on the wiring substrate;
a resin insulating member on the wiring substrate and adjacent a side of the semiconductor chip;
a wiring formed on the insulating member and electrically connecting a terminal of the semiconductor chip and a terminal of the wiring substrate.

2. The semiconductor device according to claim 1, wherein:
the semiconductor chip has a first surface facing the wiring substrate and a second surface opposite the first surface, the terminal of the semiconductor chip being provided on the second surface.

3. The semiconductor device according to claim 1, wherein:
the terminal of the semiconductor chip is located at a first position relative to a surface of the wiring substrate and the terminal of the wiring substrate is located at a second position relative to a surface of the wiring substrate, the first and second positions being offset from one another in a direction perpendicular to a plane of the surface of the wiring substrate.

4. The semiconductor device according to claim 3, wherein:
the insulating member has a slanted surface that extends to away from the surface of the wiring substrate by a distance that corresponds to the offset of the first and second positions.

5. The semiconductor device according to claim 1, wherein:
the wiring includes a plated film.

6. The semiconductor device according to claim 5. wherein:
the wiring includes an undercoat film serving as an undercoating of the plated film with respect to the insulating member.

7. Electro-optical equipment comprising a semiconductor device according to claim 1.

8. Electronic equipment comprising a semiconductor device according to claim 1.

9. A manufacturing process of a semiconductor device provided with a wiring substrate on which a semiconductor chip is mounted, comprising the steps of:
forming a resin insulating member adjacent a side of the semiconductor chip; and
forming a wiring on the insulating member, the wiring electrically connecting a terminal of the semiconductor chip and a terminal of the wiring substrate.

10. The manufacturing process of a semiconductor device according to claim 9, wherein the step of forming the resin insulating member further comprising:
forming the resin insulating member with a slanted surface that extends away from the wiring substrate by a distance that corresponds to a positional difference of the terminal of the semiconductor chip and the terminal of the wiring substrate relative to the wiring substrate.

11. The manufacturing process of a semiconductor device according to claim 10, wherein the step of forming the wiring further comprises:
forming the wiring with a plating process.
